(19) United States
(12) Patent Application Publication
(10) Pub. No.: US 2024/0191340 A1
(43) Pub. Date: Jun. 13, 2024

(54) BIAS MAGNETIC FIELD CONTROL METHOD, CONTROL DEVICE, AND SEMICONDUCTOR PROCESS EQUIPMENT

(71) Applicant: BEIJING NAURA MICROELECTRONICS EQUIPMENT CO., LTD., Beijing (CN)

(72) Inventors: Yujie GENG, Beijing (CN); Kuanmao WANG, Beijing (CN); Yujie YANG, Beijing (CN); Jinguo ZHENG, Beijing (CN)

(21) Appl. No.: 18/390,612

(22) Filed: Dec. 20, 2023

Related U.S. Application Data
(63) Continuation-in-part of application No. 17/614,479, filed on Nov. 26, 2021.

(30) Foreign Application Priority Data
May 30, 2019 (CN) 201910461432.5

(51) Int. Cl. C23C 14/35; C23C 14/14; C23C 14/54; H01F 7/02; H01J 37/34

(52) U.S. Cl. CPC C23C 14/35; C23C 14/14; C23C 14/54; H01F 7/02; H01J 37/3455; H01J 37/3461; H01J 37/3479; H01J 2237/332

(57) ABSTRACT

A bias magnetic field control method includes: in response to a consumption time length of a material of a target reaching a first preset time length of consuming the material of the target, rotating a bias magnetic field device by a fixed angle along a circumferential direction of a base, and repeatedly rotating the bias magnetic field device after every first preset time length of consuming the material of the target, to periodically change an area, where a bias magnetic field is applied to, of a surface of the target until a total time length of consuming the material of the target accumulates to reach an upper limit. Each time, the bias magnetic field device is rotated in a same direction and each time, a number of substrates is deposited by the material of the target.

### CROSS-REFERENCES TO RELATED APPLICATIONS

This application is a continuation-in-part of application Ser. No. 17/614,479, filed on Nov. 26, 2021, which is a national phase entry under 35 U.S.C. § 371 of International Application No. PCT/CN2020/089604, filed on May 11, 2020, which claims priority to Chinese Application No. 201910461432.5, filed on May 30, 2019, the entire contents of all of which are incorporated herein by their references.

### TECHNICAL FIELD

The present disclosure generally relates to the microelectronics technology field and, more particularly, to a bias magnetic field control method, a control device for a magnetic thin film deposition chamber, and a semiconductor process equipment.

### BACKGROUND

With the development of technology, a size of a processor is significantly reduced in the integrated circuit manufacturing process. However, core elements, such as integrated inductors and noise suppressors, face high frequency, miniaturization, and integration difficulties. To solve this problem, soft magnetic film materials with high magnetization, high permeability, high resonance frequency, and high resistivity have attracted more and more attention.

The soft magnetic film materials are mainly considered for the high permeability and the high magnetization of the soft magnetic film materials, as well as low coercivity and low loss. One of the main factors that influence the development of the soft magnetic film materials is the cut-off frequency of the soft magnetic film materials. By adjusting the in-plane uniaxial anisotropy field of the soft magnetic film, the cut-off frequency of the soft magnetic film materials can be adjusted. A common method to control the in-plane uniaxial anisotropy field of the soft magnetic film is magnetic field induced deposition, which has advantages including simple process, no additional process steps, and less damage to chips and is a preferred method for industrial production.

A bias magnetic field device may be configured to form a horizontal magnetic field in a deposition chamber so that when the magnetic material is sputtered and deposited, the magnetic domain of the magnetic material is aligned in the horizontal direction to form an in-plane anisotropic magnetic film. However, in the magnetic material sputtering process with a bias magnetic field, two coupling and superposition effects exist between the added bias magnetic field and the magnetic field in the corresponding area of the target surface. One effect is superposition enhancement, and the other effect is superposition weakening. The difference between these two effects leads to uneven plasma density distribution, which causes the material sputtering rate in the area of the magnetic field superposition enhancement to be higher than that in the area of the magnetic field superposition weakening. After a certain number of substrates are processed, a target recessed depth corresponding to a magnetic field enhancement area on the target surface is significantly greater than a target recessed depth corresponding to the magnetic field weakening area. That is, the target surface and the area corresponding to the bias magnetic field will have two different recessed depths, which causes many problems in the magnetic material sputtering process as follows.

First, the area with greater recessed depth on the target surface may be sputtered through quickly, which causes the effective life of the target to be reduced significantly and the utilization rate of the target to be very low.

Second, the uneven recessed depths on the target surface may cause the thickness of the sputtering material deposited on the entire substrate to be uneven. As the consumption of the target increases, the difference in the recessed depths increases, and the uniformity of the magnetic film deposited on the substrate decreases.

### SUMMARY

One aspect of the present disclosure provides a bias magnetic field control method, including: in response to a consumption time length of a material of a target reaching a first preset time length of consuming the material of the target, rotating a bias magnetic field device by a fixed angle along a circumferential direction of a base, and repeatedly rotating the bias magnetic field device after every first preset time length of consuming the material of the target, to periodically change an area, where a bias magnetic field is applied to, of a surface of the target until a total time length of consuming the material of the target accumulates to reach an upper limit. Each time, the bias magnetic field device is rotated in a same direction and each time, a number of substrates is deposited by the material of the target.

In one embodiment, before rotating the bias magnetic field device by the fixed angle along the circumferential direction, in response to the material of the target being consumed after a second preset consumption time length, the method further includes measuring a center angle corresponding to an arc length of a deepest recessed area or a shallowest recessed area formed on the surface of the target, the fixed angle being smaller than or equal to the center angle.

In one embodiment, the first preset time length and the second preset time length include a time length required for consumption of the target to reach n KWh, wherein n being a constant greater than or equal to 10 and KWh is a unit of lifetime of the target.

In one embodiment, during a sputtering process, a position of the bias magnetic field device is unchanged; and each time after reaching the first preset time length, the sputtering process is stopped, and the bias magnetic field device is rotated by the fixed angle along the circumferential direction of the base.

In one embodiment, a sum of fixed angles after repeatedly rotating the bias magnetic field device is greater than or equal to 180°.

In one embodiment, the bias magnetic field is a horizontal bias magnetic field, a magnetic film layer is deposited on the substrates, and a material of the magnetic film layer includes NiFe alloy, amorphous magnetic material, and magnetic material containing Co-base, Fe-base, and/or Ni-base.

Another aspect of the present disclosure provides a control device for a magnetic thin film deposition chamber. The control device includes one or more processors; and at least one memory coupled with the one or more processors and containing computer program instructions that, when being executed, causes the one or more processors to determine consumption time length of consuming a material of a target reaches a first preset time length of consuming the material, control a rotation of a bias magnetic field device by a fixed angle along a circumferential direction of a base, repeatedly rotate the bias magnetic field device after every first preset time length of consuming the material of the target, to periodically change an area, where a bias magnetic field is applied to, of a surface of the target until a total time length of consuming the material of the target accumulates to reach an upper limit. Each time, the bias magnetic field device is rotated in a same direction, and each time, a number of substrates is deposited by the material of the target.

In one embodiment, the control device is further configured to: before rotating the bias magnetic field device by the fixed angle along the circumferential direction, in response to the material of the target being consumed after a second preset consumption time length, measure a center angle corresponding to an arc length of a deepest recessed area or a shallowest recessed area formed on the surface of the target, the fixed angle being smaller than or equal to the center angle.

Another aspect of the present disclosure provides a semiconductor process equipment, including a magnetic thin film deposition chamber that includes a chamber body including a base configured to carry a substrate; and a target arranged at a top inside the chamber body. A bias magnetic field device is configured to form a horizontal magnetic field above the base, the horizontal magnetic field being used to deposit a magnetic film layer on the substrate over the base; a control device configured to: determine consumption time length of consuming a material of the target received reaches a first preset time length of consuming the material, control a rotation of a bias magnetic field device by a fixed angle along a circumferential direction of a base, repeatedly rotate the bias magnetic field device after every first preset time length of consuming the material of the target, to periodically change an area, where a bias magnetic field is applied to, of a surface of the target until a total time length of consuming the material of the target accumulates to reach an upper limit. Each time, the bias magnetic field device is rotated in a same direction, and each time, a number of substrates is deposited by the material of the target.

The present disclosure includes the following beneficial effects.

In the technical solutions of the bias magnetic field control method, the magnetic thin film deposition method, the chamber, and the apparatus of the present disclosure, by rotating the bias magnetic field device by the fixed angle along the circumferential direction of the base every first preset consumption time length of the target, an area on the surface of the target where the bias magnetic field acts on can periodically be changed. Thus, an excessive recessed depth in the local area of the target surface may be avoided, and meanwhile, the difference of the recessed depths of the target between different positions on the target surface may be avoided. Therefore, the lifetime of consuming the target may be increased, and the utilization rate of the target and the film thickness uniformity may be improved to reduce the manufacturing cost.

### BRIEF DESCRIPTION OF THE DRAWINGS

FIG. 1 is a schematic cross-sectional diagram of a magnetic film deposition chamber according to embodiments of the present disclosure.

FIG. 2 is a schematic exploded diagram of a bias magnetic field device according to embodiments of the present disclosure.

FIG. 3 is a schematic block flowchart of a bias magnetic field control method according to embodiments of the present disclosure.

FIG. 4 is a schematic layout diagram showing recessed areas of a target surface according to embodiments of the present disclosure.

FIG. 5 is a schematic diagram showing a rotation process of the bias magnetic field device according to embodiments of the present disclosure.

FIG. 6 is a schematic block flowchart of a magnetic thin film deposition method according to embodiments of the present disclosure.

### DETAILED DESCRIPTION OF THE EMBODIMENTS

The following disclosure provides a plurality of embodiments or examples, which can be used to realize different features of the present disclosure. The specific examples of assemblies and configurations described below are used to simplify the present disclosure. It is noted that these descriptions are only examples and are not intended to limit the content of the present disclosure. For example, in the following description, forming a first feature on or above a second feature may include the first and second features being in direct contact with each other in some embodiments and additional assemblies being formed between the above-mentioned first and second features in some embodiments, so that the first and second features may not be in direct contact. In addition, in the present disclosure, assembly symbols and/or signs may be reused in a plurality of embodiments. Such reuse is based on the purpose of brevity and clarity and does not represent the relationship between different embodiments and/or configurations discussed.

In addition, the spatially relative terms used here, such as “below,” “under,” “lower than,” “above,” “on,” and similar, may be used to facilitate the description of the relationship between one assembly or feature relative to another or a plurality of assemblies or features shown in the figure. The original meaning of these spatially relative terms covers not only the orientation shown in the figure but also various orientations of the device in application or operation. The device may be placed in other orientations (for example, rotation of 90 degrees or in other orientations), and these spatially relative terms should be explained accordingly.

Although numerical ranges and parameters used to define a broader scope of the present disclosure are approximate numerical values, the relevant numerical values of specific embodiments are presented here as accurately as possible. However, any value inherently inevitably contains standard deviations due to individual test methods. Here, “about” usually means that the actual value is within plus or minus 10%, 5%, 1%, or 0.5% of a specific value or range. Alternatively, the word “about” means that the actual value falls within the acceptable standard error of the average value, according to the consideration of those of ordinary skill in the art to which the present disclosure belongs. It is noted that, in addition to experimental examples, or unless otherwise specifically stated, all ranges, quantities, values, and percentages used herein (for example, the amount of material, time length, temperature, operation conditions, quantity ratio, and other similar values) have been modified by “about.” Therefore, unless otherwise specified to the contrary, the numerical parameters disclosed in the present disclosure and the accompanying scope of the present disclosure are approximate values and can be changed as needed. At least these numerical parameters should be understood as the indicated effective digit number and the value obtained by applying the general carry method. Here, the numerical range is expressed from one endpoint to another endpoint or between the two endpoints. Unless otherwise specified, the numerical range described here includes the endpoints.

Embodiments of the present disclosure provide a magnetic thin film deposition chamber, a semiconductor process equipment, and a bias magnetic field control method.

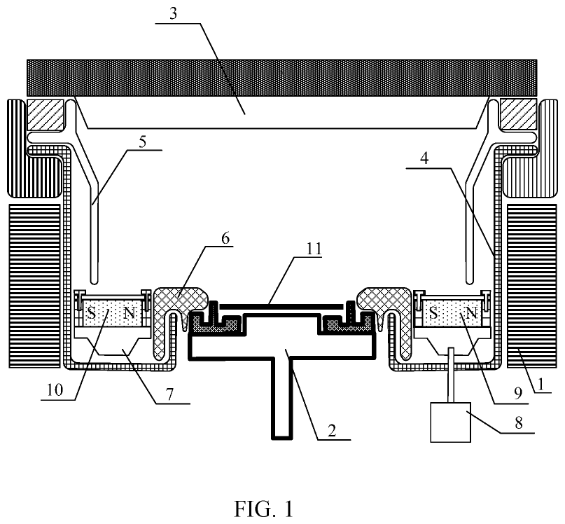

FIG. 1 is a schematic cross-sectional diagram of a magnetic film deposition chamber according to some embodiments of the present disclosure. Referring to FIG. 1, the magnetic thin film deposition chamber includes a chamber body 1 and a shielding assembly. A target 3 is arranged on the top of the chamber body 1. A base is arranged under the target 3 in the chamber body 1. The base is configured to carry a to-be-processed workpiece 7. The shielding assembly includes an upper shielding ring 5, a lower shielding ring 4, and a pressing ring 6. The lower shielding ring 4 is arranged around an inner side of a sidewall of the chamber body 1. The upper shield ring 5 is arranged around an inner side of the lower shield ring 4. The upper shielding ring 5 and the lower shielding ring 4 are configured to prevent the sputtered target from being deposited on the sidewall of the chamber body 1. The pressing ring 6 is configured to press an edge area of the upper surface of the to-be-pressed workpiece 11 when the base 2 is in a process position to fix the to-be-processed workpiece 11 on the base 2. FIG. 1 only illustrates a portion of the chamber body 1 above the base 2 and a portion of the chamber body 1 below the target 3 schematically. The remaining portion is not shown.

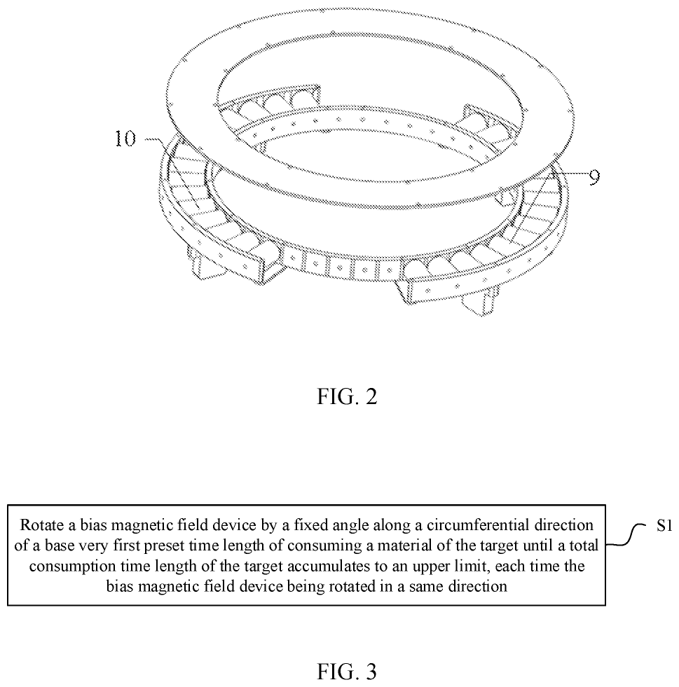

The magnetic film deposition chamber further includes a bias magnetic field device. The bias magnetic field device is configured to form a bias magnetic field above the base 2. The bias magnetic field is a horizontal magnetic field. The horizontal magnetic field is used to deposit a magnetic film layer on the to-be-processed workpiece 11. FIG. 2 is a schematic exploded diagram of a bias magnetic field device according to some embodiments of the present disclosure. With reference to FIG. 2, in some embodiments, the bias magnetic field device includes two sets of magnets (9, 10) arranged oppositely on the inner side of the sidewall of the chamber body 1 and around the base 2. The two sets of magnets (9, 10) are configured to form the above-mentioned horizontal magnetic field above the base 2. Specifically, each magnet set includes a plurality of magnetic columns, which are arranged at intervals along the circumferential direction of the base 2 to form an arc shape. In addition, each magnetic column is arranged horizontally. An N pole of each magnetic column in one magnet set 10 and an S pole of each magnetic column in the other magnet set 9 face the base 2.

Of course, in practical applications, the bias magnetic field device may also adopt any other structure, as long as a horizontal magnetic field can be formed above the base 2 to obtain an in-plane anisotropic magnetic film. For example, the magnet set includes two arc-shaped magnets, which surround the two sides of the base symmetrically. The N pole of one magnet and the S pole of the other magnet face the base. For another example, the magnet set includes a closed ring-shaped magnet. The ring-shaped magnet is made of permanent magnet material to form the horizontal magnetic field in an overall magnetization manner. In addition, the above-mentioned magnetic column or magnet may include a permanent magnet or an electromagnet.

It needs to be noted, in some embodiments, the bias magnetic field device is arranged on the inner side of the sidewall of the chamber body 1. However, the present disclosure is not limited to this. In practical applications, the bias magnetic field device may also be arranged on the outside of the sidewall of the chamber body 1.

In some embodiments, the magnetic thin film deposition chamber further includes a control device for controlling the bias magnetic field. The control device may be a computer apparatus. The bias magnetic field control device is configured to drive the bias magnetic field device to rotate the fixed angle along the circumferential direction of the base 2. Specifically, the bias magnetic field control device includes a rotation platform 7 and a rotation drive mechanism 8. The rotation platform 7 is configured to support the above-mentioned bias magnetic field device. Specifically, the rotation platform 7 is ring-shaped and surrounds the base 2. The two sets of magnets (9, 10) are all arranged on the rotation platform 7. The rotation drive mechanism 8 is configured to drive the rotation platform 7 to rotate around the axis of the base 2 by the fixed angle.

In some embodiments, the rotation platform 7 may be made of a non-magnetic material to avoid interference with the bias magnetic field, for example, stainless steel.

Various embodiments also provide a semiconductor process equipment including the magnetic thin film deposition chamber and a control device.

The control device may include, for example, a computer that includes at least one memory for storing computer program instructions; and one or more processors coupled to the at least one memory. The computer program instructions, when being executed, may cause the one or more processors to perform, e.g., the disclosed bias magnetic field control method.

In one embodiment, the control device may be configured to obtain consumption time length of consuming a target material of a target and may then determine the control of the bias magnetic field device accordingly.

The control device may determine if the consumption time length of the target material satisfies a first preset time length of consuming the target material. If it is satisfied, in response to the consumption time length of the material of the target reaching the first preset time length of consuming the material of the target, the control device may send a signal to the rotation drive mechanism to drive the bias magnetic field device to rotate.

In one embodiment, the bias magnetic field device may be driven to rotate by a fixed angle along a circumferential direction of the base after every first preset time length of consuming the target material of the target is reached. A corresponding area, where a bias magnetic field is applied to, of a surface of the target may thus be periodically changed after each first preset time length, until a total time length of consuming the target material accumulates to reach an upper limit. Each time, the bias magnetic field device is rotated in a same direction. Each time, a number of substrates is deposited by the material of the target.

In one embodiment, before the bias magnetic field device is driven to rotate by the fixed angle along the circumferential direction of the base, the target may have been previously consumed, e.g., after a second preset time length, and the target may be examined. For example, after the second preset time length of consuming the target material and before the bias magnetic field device is driven to rotate by the fixed angle along the circumferential direction of the base, a center angle corresponding to an arc length of a deepest recessed area or a shallowest recessed area formed on surface of the target may be measured. The measurement information may be sent to the control device, e.g., stored in the at least one memory or written into the computer program instructions of the control device. The fixed angle may be smaller than or equal to the center angle. In one embodiment, the second preset time length may be longer than or equal to the first preset time length.

The target in the magnetic thin film deposition chamber may be measured at desired times, e.g., upon equipment's verification and/or after a time length of consuming the target material, without interrupting the deposition of the target material.

With reference to FIG. 3, embodiments of the present disclosure provide a bias magnetic field control method. The bias magnetic field control device of embodiments of the present disclosure may be used to perform control. The method includes the following step.

At S1, the bias magnetic field device is rotated by the fixed angle along the circumferential direction of the base 2 every first preset consumption time length of the target until a total consumption time length of the target 3 accumulates to reach the upper limit.

In one embodiment, for performing operation S1, a consumption time length of a material of a target is obtained. In response to the consumption time length of the material of the target reaching a first preset time length of consuming the material of the target, a bias magnetic field device may be controlled to rotate by a fixed angle along a circumferential direction of a base, followed by repeatedly rotating the bias magnetic field device after every first preset time length of consuming the material of the target, to periodically change an area, where a bias magnetic field is applied to, of a surface of the target until a total time length of consuming the material of the target accumulates to reach an upper limit.

In the entire sputtering process, each time after a certain number of substrates are deposited, that is, each time the consumption time length of the target reaches the preset time length (the first preset consumption time length), the bias magnetic field device may be rotated once. Each time the rotated angle is the same. That is, each time the bias magnetic field device may be rotated the fixed angle clockwise or counterclockwise along the circumferential direction of the base 2.

Preferably, during the sputtering process, the position of the bias magnetic field device is fixed. When the first preset consumption time length is reached, the sputtering process may be stopped. The bias magnetic field device may be rotated at the fixed angle along the circumferential direction of the base 2. Then, the sputtering process may be restarted. The timer may be reset until the next first preset consumption time length is reached. The process may repeat until the target is completely consumed. As such, the rotation of the bias magnetic field device may be prevented from impacting the sputtering process. The sputtering process may be ensured to be performed normally.

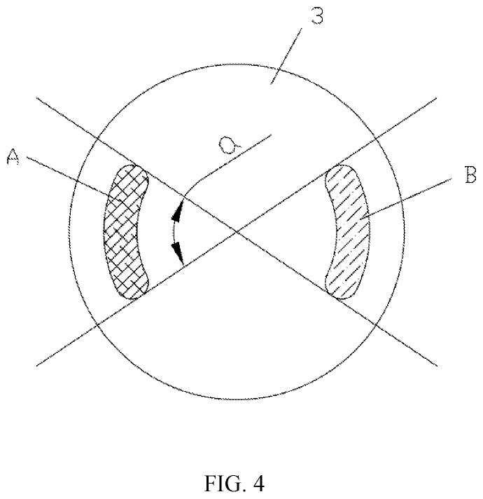

Before the rotation angle of the bias magnetic field device is changed, and after the target 3 has been used for a length of time, the areas on the surface of the target corresponding to the bias magnetic field may have depressions with two different depths. As shown in FIG. 4, a deepest recessed area A corresponding to the magnetic field enhancement area and a shallowest recessed area B corresponding to the magnetic field weakening area may appear on the surface of the target. Corresponding to the arc shapes of the two sets of magnets (9, 10), the deepest recessed area A and the shallowest recessed area B are approximately in two symmetrical arc shapes. The central angle a corresponds to the arc length of the deepest recessed area A or the shallowest recessed area B in the circumferential direction of the target 3.

A NiFe target with a diameter of 444 mm and a thickness of 2˜3 mm is taken as an example. After measurement, when the target consumes 50 KWh, the average depth of the deepest recessed area A on the target surface may be 1.64 mm, and the average depth of the shallowest recessed area B may be 1.40 mm. The center angle corresponding to the arc length of the deepest recessed area A or the shallowest recessed area B in the circumferential direction of the target 3 may be 100°.

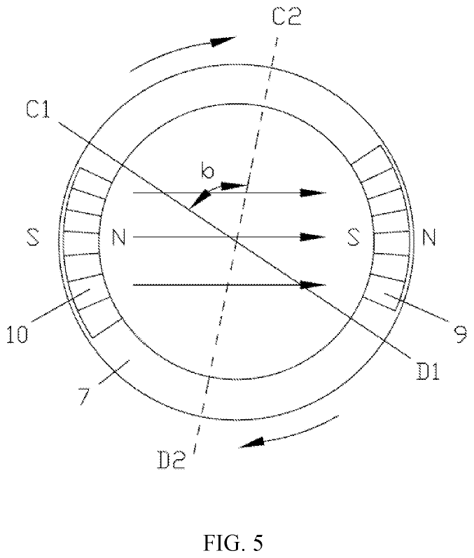

As shown in FIG. 5, after the first preset consumption time length, the bias magnetic field device is rotated along the circumferential direction of the base 2 by fixed angle b. Specifically, in some embodiments, for the magnet set 10, one end of the arc may be rotated clockwise from position C1 to position C2, and the rotation angle may be fixed angle b. Meanwhile, for the magnet set 9, one end of the arc may be rotated clockwise from position D1 to position D2, and the rotation angle may be fixed angle b. The above process is periodically performed until the total consumption time length of the target 3 accumulated to reach the upper limit. The total consumption time length of the target 3 may be the sum of the first preset consumption time lengths. The upper limit may be the time length required for exhausting the target 3.

Optionally, the above-mentioned first preset consumption time length may be the time length required for the consumption of the target to reach n KWh. KWh is a unit of the lifetime of the target. n may be a constant greater than or equal to 10, for example, n may equal to 50.

By rotating the bias magnetic field device by the fixed angle along the circumferential direction of the base every first preset consumption time length of the target 3, the area of the target surface where the bias magnetic field acts on may be periodically changed. That is, the bias magnetic field may not always act on the same area on the target surface but periodically act on different areas in the circumferential direction of the target surface. As such, the excessive recessed depth in the local area of the target surface may be avoided. Meanwhile, the excessive difference in target recessed depths between different positions on the target surface may be avoided. Thus, the lifetime of consuming the target may be increased, and the utilization rate of the target and the film thickness uniformity may be improved to reduce the manufacturing cost.

Preferably, before step S1, the method includes the following step.

At S0, after a second preset consumption time length of the target 3, the center angle corresponding to the arc length of the deepest recessed area or the shallowest recessed area formed on the surface of the target 3 is measured. The second preset consumption time length is longer than or equal to the first preset consumption time length.

In step S1, the fixed angle is less than or equal to the center angle. As such, the action area of the bias magnetic field may be avoided from covering the entire circumference of the target surface. Thus, the uniformity of the recessed depth of the target surface may be improved.

The above-mentioned second preset consumption time length may be the time length required for the consumption of the target to reach n KWh. KWh is a unit of the lifetime of the target. n may be a constant greater than or equal to 10, for example, n may be equal to 50.

Preferably, taking FIGS. 4 and 5 as examples, fixed angle b is equal to center angle a. As such, the action area of the bias magnetic field may cover the entire circumference of the target surface, and the bias magnetic fields generated by the bias magnetic field devices of different angles may be prevented from overlapping. Thus, the uniformity of the recessed depth of the target surface may be further improved.

Preferably, in step S1, the sum of a plurality of fixed angles of multiple rotations of the bias magnetic field device may be greater than or equal to 180°. As such, the action area of the bias magnetic field may be avoided from covering the entire circumference of the target surface. Thus, the uniformity of the recessed depth of the target surface may be improved.

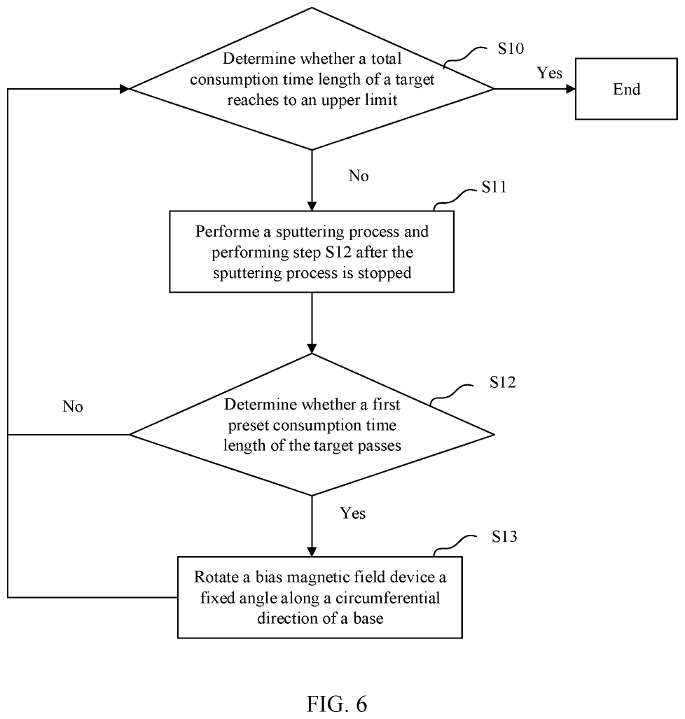

As another technical solution, referring to FIG. 6, embodiments of the present disclosure further provide a magnetic thin film deposition method for depositing a magnetic film layer on a to-be-processed workpiece. The bias magnetic field used may include a horizontal magnetic field. The method includes the above-mentioned bias magnetic field control method provided by embodiments of the present disclosure. Specifically, the method includes the following steps:
S10, determining whether the total consumption time length of the target accumulates to reach the upper limit, if yes, stopping the process, and if not, performing step S11;
S11, performing the sputtering process, and perform step S12 after the sputtering process stops;
S12, determining whether the first preset consumption time length of the target passes, if yes, performing step S13, if not, returning to step S10; and
S13, rotating the bias magnetic field device the fixed angle along the circumferential direction of the base 2 and returning to step S10.

The magnetic thin film deposition method provided by embodiments of the present disclosure includes the above-mentioned bias magnetic field control method provided by embodiments of the present disclosure. Thus, the excessive recessed depth of the local area of the target surface may be avoided. Meanwhile, the excessive difference of the target recessed depths between different positions on the target surface may be avoided. The lifetime of consuming the target may be increased, and the utilization rate of the target and the thickness uniformity of the thin film may be improved to reduce the manufacturing cost.

Optionally, the material of the above-mentioned magnetic film layer includes NiFe alloy, amorphous magnetic material, and magnetic material containing Co-base, Fe-base, and/or Ni-base. The NiFe alloy includes, for example, Ni80Fe20, Ni45Fe55, Ni81Fe19, etc. The amorphous magnetic material includes, for example, CoZrTa. The magnetic material containing Co-base, Fe-base, and/or Ni-base includes, for example, Co60Fe40, NiFeCr, etc.

As another technical solution, the present disclosure also provides a magnetic thin film deposition device, which includes at least one deposition chamber for depositing a magnetic film layer. The deposition chamber includes the above-mentioned magnetic film deposition chamber provided by embodiments of the present disclosure.

With the magnetic film deposition equipment provided by the present disclosure, by using the above magnetic film deposition chamber of embodiments of the present disclosure, the service life of the target material may be increased, and the utilization rate of the target material and the thickness uniformity of the film may be improved to reduce the manufacturing cost.

It can be understood that above embodiments are merely exemplary embodiments used to illustrate the principle of the present disclosure, but the present disclosure is not limited to this. For those of ordinary skill in the art, various modifications and improvements may be made without departing from the spirit and essence of the present disclosure. These modifications and improvements are also within the protection scope of the present disclosure.

What is claimed is:

1. A bias magnetic field control method, comprising:
in response to a consumption time length of a material of a target reaching a first preset time length of consuming the material of the target, rotating a bias magnetic field device by a fixed angle along a circumferential direction of a base, and
repeatedly rotating the bias magnetic field device after every first preset time length of consuming the material of the target, to periodically change an area, where a bias magnetic field is applied to, of a surface of the target until a total time length of consuming the material of the target accumulates to reach an upper limit, wherein
each time, the bias magnetic field device is rotated in a same direction and
each time, a number of substrates is deposited by the material of the target.

2. The method according to claim 1, further comprising, before rotating the bias magnetic field device by the fixed angle along the circumferential direction,
in response to the material of the target being consumed after a second preset consumption time length, measuring a center angle corresponding to an arc length of a deepest recessed area or a shallowest recessed area formed on the surface of the target, the fixed angle being smaller than or equal to the center angle.

3. The method according to claim 2, wherein the first preset time length and the second preset time length include a time length required for consumption of the target to reach n KWh, wherein n being a constant greater than or equal to 10 and KWh is a unit of lifetime of the target.

4. The method according to claim 2, wherein:
during a sputtering process, a position of the bias magnetic field device is unchanged; and
each time after reaching the first preset time length, the sputtering process is stopped, and the bias magnetic field device is rotated by the fixed angle along the circumferential direction of the base.

5. The method according to claim 1, wherein a sum of fixed angles after repeatedly rotating the bias magnetic field device is greater than or equal to 180°.

6. The method according to claim 1, wherein
the bias magnetic field is a horizontal bias magnetic field,
a magnetic film layer is deposited on the substrates, and
a material of the magnetic film layer includes NiFe alloy, amorphous magnetic material, and magnetic material containing Co-base, Fe-base, and/or Ni-base.

7. A control device for a magnetic thin film deposition chamber, comprising:
one or more processors; and
at least one memory coupled with the one or more processors and containing computer program instructions that, when being executed, cause the one or more processors to:
determine consumption time length of consuming a material of a target received reaches a first preset time length of consuming the material,
control a rotation of a bias magnetic field device by a fixed angle along a circumferential direction of a base, and
repeatedly rotate the bias magnetic field device after every first preset time length of consuming the material of the target, to periodically change an area, where a bias magnetic field is applied to, of a surface of the target until a total time length of consuming the material of the target accumulates to reach an upper limit, wherein
each time, the bias magnetic field device is rotated in a same direction, and
each time, a number of substrates is deposited by the material of the target.

8. The control device according to claim 7, wherein the control device is further configured to:
before rotating the bias magnetic field device by the fixed angle along the circumferential direction, in response to the material of the target being consumed after a second preset consumption time length, measure a center angle corresponding to an arc length of a deepest recessed area or a shallowest recessed area formed on the surface of the target, the fixed angle being smaller than or equal to the center angle.

9. The control device according to claim 7, wherein the first preset time length and the second preset time length include a time length required for consumption of the target to reach n KWh, wherein n being a constant greater than or equal to 10 and KWh is a unit of lifetime of the target.

10. The control device according to claim 8, wherein:
during a sputtering process, a position of the bias magnetic field device is unchanged; and
each time after reaching the first preset time length, the sputtering process is stopped, and the bias magnetic field device is rotated by the fixed angle along the circumferential direction of the base.

11. The control device according to claim 7, wherein a sum of fixed angles after repeatedly rotating the bias magnetic field device is greater than or equal to 180°.

12. The control device according to claim 7, wherein the bias magnetic field is a horizontal bias magnetic field,
a magnetic film layer is deposited on the substrates, and
a material of the magnetic film layer includes NiFe alloy, amorphous magnetic material, and magnetic material containing Co-base, Fe-base, and/or Ni-base.

13. A semiconductor process equipment comprising:
a magnetic thin film deposition chamber comprising:
a chamber body including a base configured to carry a substrate; and
a target arranged at a top inside the chamber body;
a bias magnetic field device configured to form a horizontal magnetic field above the base, the horizontal magnetic field being used to deposit a magnetic film layer on the substrate over the base;
a control device configured to:
determine a consumption time length of consuming the material of the target reaches a first preset time length of consuming the material,
control a rotation of a bias magnetic field device by a fixed angle along a circumferential direction of a base, and
repeatedly rotate the bias magnetic field device after every first preset time length of consuming the material of the target, to periodically change an area, where a bias magnetic field is applied to, of a surface of the target until a total time length of consuming the material of the target accumulates to reach an upper limit, wherein
each time, the bias magnetic field device is rotated in a same direction, and
each time, a number of substrates is deposited by the material of the target.

14. The semiconductor process equipment according to claim 13, wherein the control device is further configured to:
before rotating the bias magnetic field device by the fixed angle along the circumferential direction, in response to the material of the target being consumed after a second preset consumption time length, measure a center angle corresponding to an arc length of a deepest recessed area or a shallowest recessed area formed on the surface of the target, the fixed angle being smaller than or equal to the center angle.

15. The semiconductor process equipment according to claim 13, further comprising:
a rotation platform made of non-magnetic material and configured to support the bias magnetic field device; and
a rotation drive mechanism configured to drive the rotation platform to rotate the fixed angle around an axis of the base.

16. The semiconductor process equipment according to claim 13, wherein the bias magnetic field device is arranged on an inner side of a sidewall of the chamber body and around the base, or around the chamber body on an outer side of the sidewall of the chamber body.

17. The semiconductor process equipment according to claim 13, wherein:
during a sputtering process, a position of the bias magnetic field device is unchanged; and
each time in response to reaching the first preset time length, the sputtering process is stopped, and the bias magnetic field device is rotated the fixed angle along the circumferential direction of the base.

18. The semiconductor process equipment according to claim 13, wherein:
a material of the magnetic film layer includes NiFe alloy, amorphous magnetic material, and magnetic material containing Co-base, Fe-base, and/or Ni-base.
